(19) United States
(12) Patent Application Publication
(10) Pub. No.: US 2026/0303060 A1
(43) Pub. Date: Oct. 1, 2026

(54) Resonator Element

(71) Applicant: SEIKO EPSON CORPORATION, Tokyo (JP)

(72) Inventors: Ryo NIIDE, Hokuto (JP); Toshiki KANAI, Shiojiri (JP); Makoto FURUHATA, Matsumoto (JP)

(21) Appl. No.: 19/577,522

(22) Filed: Mar. 25, 2026

(30) Foreign Application Priority Data
Mar. 26, 2025 (JP) 2025-051225
Mar. 26, 2025 (JP) 2025-051234

(51) Int. Cl. H03H 9/17; H03H 9/13

(52) U.S. Cl. CPC H03H 9/17; H03H 9/13

(57) ABSTRACT

A resonator element includes a vibrating substrate including a base portion, and a first vibrating arm, a second vibrating arm, and a third vibrating arm, each of the first, second, and third vibrating arms extending from the base portion in a Y-axis direction and being arranged side by side in an X-axis direction, the first vibrating arm being disposed between the second vibrating arm and the third vibrating arm in plan view from a Z-axis direction. The resonator element further includes a first piezoelectric element disposed across the first vibrating arm and the base portion to cause the first vibrating arm to perform flexural vibration in the Z-axis direction by expanding and contracting in the Y-axis direction. The first piezoelectric element includes a piezoelectric layer, a lower electrode disposed between the piezoelectric layer and the vibrating substrate, and an upper electrode overlapping the lower electrode via the piezoelectric layer. In each of the lower electrode and the upper electrode of the first piezoelectric element, a film thickness of a first portion overlapping a boundary between the base portion and the first vibrating arm is larger than a film thickness of a second portion located closer to a tip end side of the first vibrating arm than the first portion.

The present application is based on, and claims priorities from JP Application Serial Number 2025-051225, filed Mar. 26, 2025, and JP Application Serial Number 2025-051234, filed Mar. 26, 2025, the disclosures of which are hereby incorporated by reference herein in its entirety.

### BACKGROUND

### 1. Technical Field

The present disclosure relates to a resonator element.

### 2. Related Art

JP-A-2012-160996 describes a silicon resonator element that includes a base portion and three vibrating arms extending from the base portion in a Y-axis direction. In addition, the three vibrating arms are arranged in an X-axis direction orthogonal to the Y-axis direction and each includes a piezoelectric element on an upper surface. The piezoelectric element has a structure in which a piezoelectric body is interposed between electrodes from above and below. When the piezoelectric elements, to which a driving voltage is applied, expand and contract, each vibrating arm vibrates in a Z-axis direction orthogonal to the X-axis and the Y-axis.

However, in the resonator element described in JP-A-2012-160996, when a stress exceeding a yield point is applied to the electrodes of the piezoelectric elements, a linear relationship between the forces applied to the vibrating arms and the deformations of the vibrating arms may be broken, and the vibration characteristics may deteriorate.

### SUMMARY

When three axes orthogonal to each other are defined as an X-axis, a Y-axis, and a Z-axis, and a direction along the X-axis is defined as an X-axis direction, a direction along the Y-axis is defined as a Y-axis direction, and a direction along the Z-axis is defined as a Z-axis direction, a resonator element according to an aspect of the present disclosure includes: a vibrating substrate including a base portion, and a first vibrating arm, a second vibrating arm, and a third vibrating arm, each of the first, second, and third vibrating arms extending from the base portion in the Y-axis direction and being arranged side by side in the X-axis direction, the first vibrating arm being disposed between the second vibrating arm and the third vibrating arm in plan view from the Z-axis direction; a first piezoelectric element disposed across the first vibrating arm and the base portion to cause the first vibrating arm to perform flexural vibration in the Z-axis direction by expanding and contracting in the Y-axis direction; a second piezoelectric element disposed across the second vibrating arm and the base portion to cause the second vibrating arm to perform flexural vibration in the Z-axis direction by expanding and contracting in the Y-axis direction; and a third piezoelectric element disposed across the third vibrating arm and the base portion to cause the third vibrating arm to perform flexural vibration in the Z-axis direction by expanding and contracting in the Y-axis direction. Each of the first piezoelectric element, the second piezoelectric element, and the third piezoelectric element includes: a piezoelectric layer; a lower electrode disposed between the piezoelectric layer and the vibrating substrate; and an upper electrode overlapping the lower electrode via the piezoelectric layer in plan view from the Z-axis direction. In the first vibrating arm, the second vibrating arm, and the third vibrating arm, when a region overlapping a boundary between the base portion and a vibrating arm is defined as a first portion, and when a region closer to a tip end side of the vibrating arm than the first portion is defined as a second portion, in each of the lower electrode and the upper electrode of the first piezoelectric element, a film thickness of the first portion is larger than a film thickness of the second portion.

When three axes orthogonal to each other are defined as an X-axis, a Y-axis, and a Z-axis, and a direction along the X-axis is defined as an X-axis direction, a direction along the Y-axis is defined as a Y-axis direction, and a direction along the Z-axis is defined as a Z-axis direction, a resonator element according to an aspect of the present disclosure includes: a vibrating substrate including a base portion, and a first vibrating arm, a second vibrating arm, and a third vibrating arm, each of the first, second, and third vibrating arms extending from the base portion in the Y-axis direction and being arranged side by side in the X-axis direction, the first vibrating arm being disposed between the second vibrating arm and the third vibrating arm in plan view from the Z-axis direction; a first piezoelectric element disposed across the first vibrating arm and the base portion to cause the first vibrating arm to perform flexural vibration in the Z-axis direction by expanding and contracting in the Y-axis direction; a second piezoelectric element disposed across the second vibrating arm and the base portion to cause the second vibrating arm to perform flexural vibration in the Z-axis direction by expanding and contracting in the Y-axis direction; and a third piezoelectric element disposed across the third vibrating arm and the base portion to cause the third vibrating arm to perform flexural vibration in the Z-axis direction by expanding and contracting in the Y-axis direction. Each of the first piezoelectric element, the second piezoelectric element, and the third piezoelectric element includes: a piezoelectric layer; a lower electrode disposed between the piezoelectric layer and the vibrating substrate; and an upper electrode overlapping the lower electrode via the piezoelectric layer in plan view from the Z-axis direction. In the first vibrating arm, the second vibrating arm, and the third vibrating arm, when a region overlapping a boundary between the base portion and a vibrating arm is defined as a first portion and a region closer to a tip end side of the vibrating arm than the first portion is defined as a second portion, each of the lower electrode and the upper electrode of the first piezoelectric element includes a first electrode film in the first portion and a second electrode film in the second portion, in which the first electrode film is connected to the second electrode film and is made of a material having a higher yield point than that of a constituent material of the second electrode film.

### BRIEF DESCRIPTION OF THE DRAWINGS

FIG. 1 is a plan view of a MEMS element according to a first embodiment.

FIG. 2 is a sectional view taken along line II-II in FIG. 1.

FIG. 3 is a plan view of a resonator element included in the MEMS element.

FIG. 4 is a sectional view of a vibrating arm included in the resonator element.

FIG. 5 is a view for explaining a yield point.

FIG. 6 is a sectional view of a piezoelectric element included in the resonator element.

FIG. 7 is a graph showing a change in resonance frequency depending on the magnitude of a driving voltage when T1=T2.

FIG. 8 is a graph showing a change in resonance frequency depending on the magnitude of a driving voltage when T1>T2.

FIG. 9 is a sectional view of the piezoelectric element included in the resonator element.

FIG. 10 is a sectional view of a vibrating arm included in a resonator element according to a second embodiment.

FIG. 11 is a sectional view of a piezoelectric element included in the resonator element according to the second embodiment.

FIG. 12 is a sectional view of a piezoelectric element according to a modification example.

FIG. 13 is a sectional view of a piezoelectric element according to a modification example.

FIG. 14 is a sectional view of a piezoelectric element according to a modification example.

FIG. 15 is a plan view showing a modification example of the resonator element.

### DESCRIPTION OF EMBODIMENTS

Hereinafter, a resonator element according to the present disclosure will be described in detail on the basis of embodiments shown in the accompanying drawings.

### First Embodiment

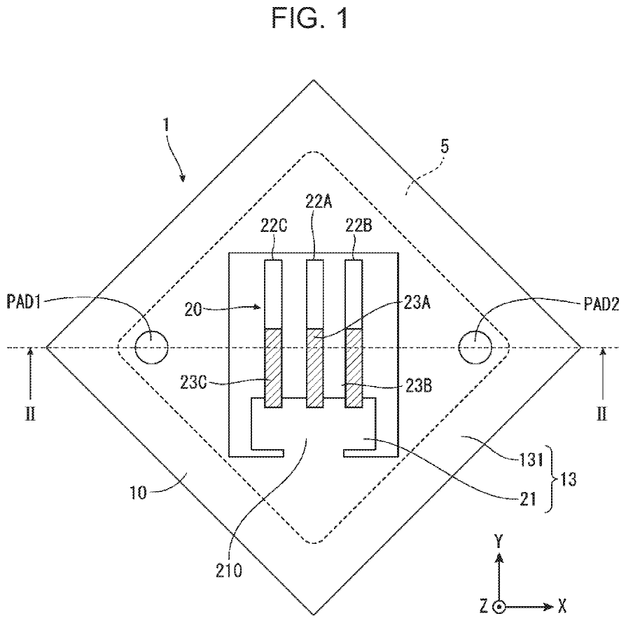

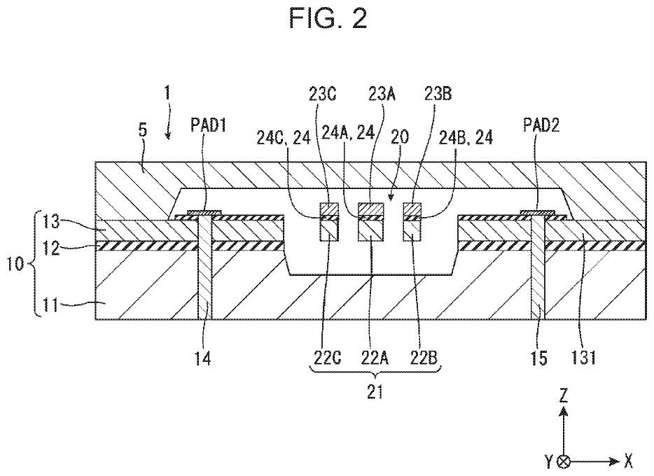

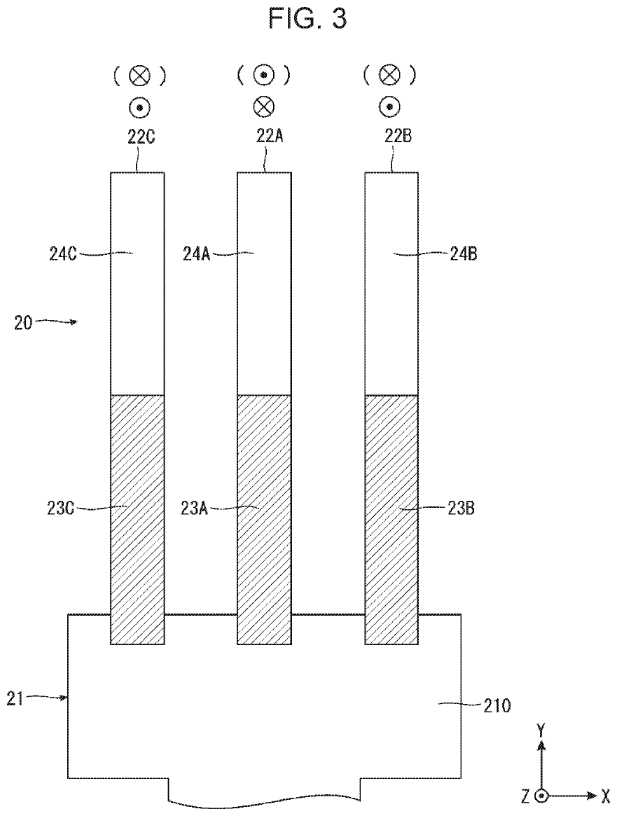

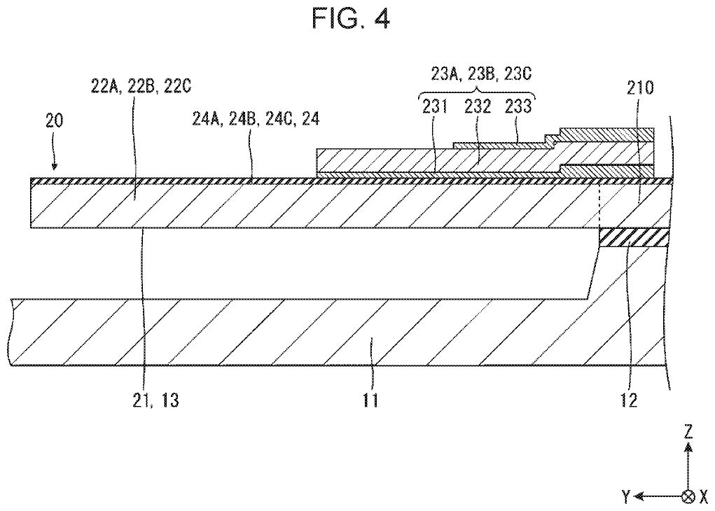

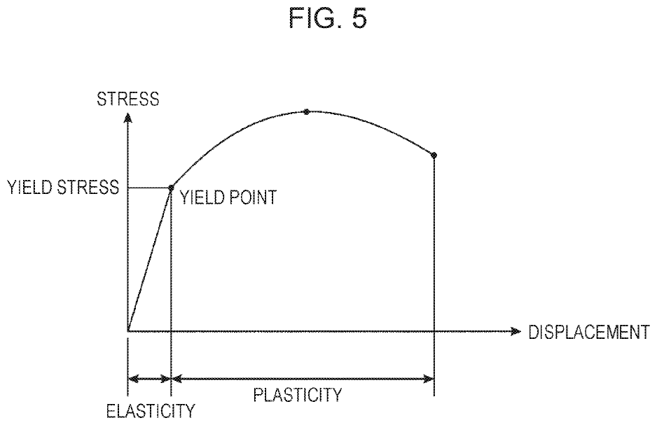

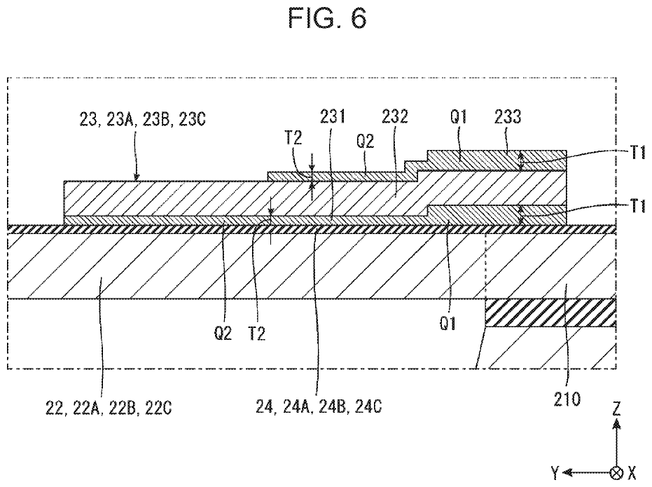

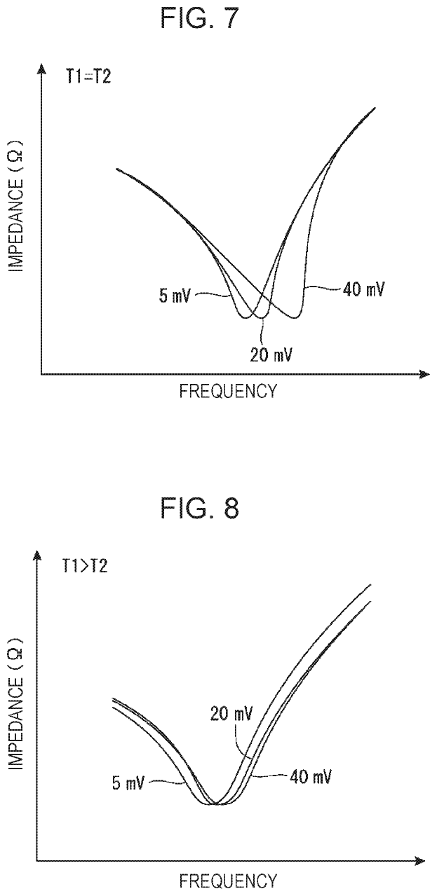

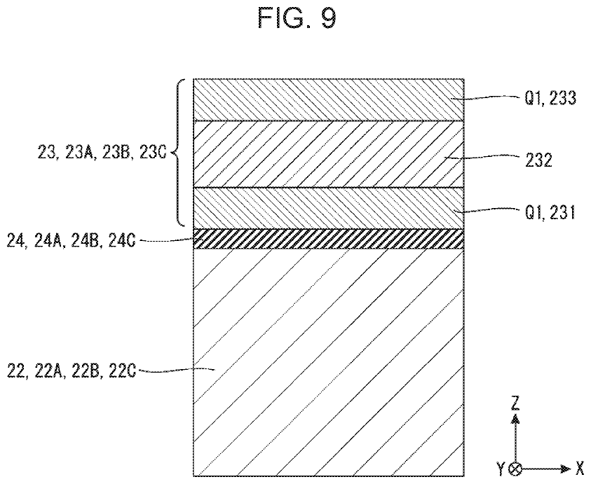

FIG. 1 is a plan view of a MEMS element according to a first embodiment. FIG. 2 is a sectional view taken along line II-II in FIG. 1. FIG. 3 is a plan view of a resonator element included in the MEMS element. FIG. 4 is a sectional view of a vibrating arm included in the resonator element. FIG. 5 is a view for explaining a yield point. FIG. 6 is a sectional view of a piezoelectric element included in the resonator element. FIG. 7 is a graph showing a change in resonance frequency depending on the magnitude of a driving voltage when T1=T2. FIG. 8 is a graph showing a change in resonance frequency depending on the magnitude of a driving voltage when T1>T2. FIG. 9 is a sectional view of the piezoelectric element included in the resonator element.

For convenience of description, an X-axis, a Y-axis, and a Z-axis orthogonal to each other are shown in each drawing. In addition, a direction along the X-axis is also referred to as an X-axis direction, a direction along the Y-axis is also referred to as a Y-axis direction, and a direction along the Z-axis is also referred to as a Z-axis direction. Herein, the X-axis direction corresponds to a “second direction”, whereas the Y-axis direction corresponds to a “first direction”. In addition, an arrow side of each axis is referred to as a positive side, whereas an opposite side is referred to as a negative side. The positive side in the Z-axis direction is also referred to as “up”, and the negative side is also referred to as “down”.

As shown in FIGS. 1 and 2, a MEMS element 1 includes a silicon-on-insulator (SOI) substrate 10 on which a resonator element 20 is formed and a lid 5 that hermetically seals the resonator element 20 between the SOI substrate 10 and the lid 5. The lid 5 is made of single-crystal silicon or the like and has a recessed portion opened on the lower surface. The lower surface of the lid 5 is joined to the upper surface of the SOI substrate 10.

As shown in FIG. 2, the SOI substrate 10 is a substrate in which a silicon layer 11 as a handle layer, a buried oxide (BOX) layer 12, and a surface silicon layer 13 as a device layer are stacked in this order from the lower side. For example, the silicon layer 11 and the surface silicon layer 13 are each made of single-crystal silicon, and the BOX layer 12 is made of a silicon oxide (SiO₂) layer.

In addition, as shown in FIG. 1, a vibrating substrate 21 included in the resonator element 20 and a frame-shaped frame 131 surrounding the periphery of the vibrating substrate 21 are formed in the surface silicon layer 13. A pair of electrode pads PAD1 and PAD2 is disposed on the upper surface of the frame 131. Further, as shown in FIG. 2, through electrodes 14 and 15 that extend through the SOI substrate 10 in a thickness direction are formed at positions overlapping the electrode pads PAD1 and PAD2, respectively. The through electrode 14 is electrically coupled to the electrode pad PAD1, and the through electrode 15 is electrically coupled to the electrode pad PAD2. As a result, the electrode pads PAD1 and PAD2 are led out to the outside from the lower surface of the MEMS element 1. Therefore, electrical coupling with an external device such as an oscillation circuit is easy.

Further, as shown in FIGS. 1 and 2, the resonator element 20 has the vibrating substrate 21 formed in the surface silicon layer 13. That is, the vibrating substrate 21 is formed of a silicon substrate. Since the vibrating substrate 21 is formed of the silicon substrate, the vibrating substrate 21 can be formed by using a silicon wafer process, and thus the vibrating substrate 21 can be easily processed, and the vibrating substrate 21 can be formed with high processing accuracy.

The vibrating substrate 21 has a plate shape and includes an upper surface and a lower surface which are in a front-back relationship. As shown in FIG. 3, the vibrating substrate 21 includes a base portion 210 and three vibrating arms 22, which are a first vibrating arm 22A, a second vibrating arm 22B, and a third vibrating arm 22C, extending from the base portion 210. As shown in FIG. 4, the base portion 210 is supported by the silicon layer 11 and the BOX layer 12 located below, whereas the first, second, and third vibrating arms 22A, 22B, and 22C are separated from the BOX layer 12. Therefore, each of the first, second, and third vibrating arms 22A, 22B, and 22C is a cantilever beam cantilevered by the base portion 210 at a base end portion.

As shown in FIG. 3, each of the first, second, and third vibrating arms 22A, 22B, and 22C extends from the base portion 210 toward the positive side in the Y-axis direction as the first direction, and the first, second, and third vibrating arms 22A, 22B, and 22C are disposed side by side at equal intervals in the X-axis direction as the second direction. Specifically, the first vibrating arm 22A is located at the center of the arrangement, the second vibrating arm 22B is located on the positive side of the first vibrating arm 22A in the X-axis direction, and the third vibrating arm 22C is located on the negative side of the first vibrating arm 22A in the X-axis direction. That is, the first vibrating arm 22A is located between the second vibrating arm 22B and the third vibrating arm 22C.

Further, as shown in FIG. 4, the resonator element 20 includes a temperature characteristic adjustment portion 24 that adjusts frequency-temperature characteristics of the resonance frequency. The temperature characteristic adjustment portion 24 includes a temperature characteristic adjustment film 24A disposed on an upper surface of the first vibrating arm 22A, a temperature characteristic adjustment film 24B disposed on an upper surface of the second vibrating arm 22B, and a temperature characteristic adjustment film 24C disposed on an upper surface of the third vibrating arm 22C.

The temperature characteristic adjustment films 24A, 24B, and 24C are made of a silicon oxide (SiO₂) layer. Silicon, which is a constituent material of the vibrating substrate 21, has frequency-temperature characteristics in which the resonance frequency decreases as the temperature increases. On the other hand, silicon oxide (SiO₂), which is a constituent material of the temperature characteristic adjustment films 24A, 24B, and 24C, has frequency-temperature characteristics in which the resonance frequency increases as the temperature increases. Therefore, these frequency-temperature characteristics cancel each other out, and the frequency-temperature characteristics of the resonance frequency of a composite formed of the first, second, and third vibrating arms 22A, 22B, and 22C and the temperature characteristic adjustment films 24A, 24B, and 24C can be made closer to flat. By disposing the temperature characteristic adjustment portion 24, for example, a change amount of approximately ±3000 ppm of the resonance frequency of the vibrating substrate 21 in the temperature range of −25° C. to ±75° C. can be flattened to approximately ±200 ppm to approximately ±500 ppm.

The configurations of the temperature characteristic adjustment films 24A, 24B, and 24C are not particularly limited, and may have a configuration in which another layer such as a zirconium oxide (ZrO₂) layer is stacked on the silicon oxide (SiO₂) layer. Further, the temperature characteristic adjustment films 24A, 24B, and 24C may also be disposed on the respective lower surfaces of the first, second, and third vibrating arms 22A, 22B, and 22C. Alternatively, the temperature characteristic adjustment portion 24 may be omitted.

As shown in FIG. 3, the resonator element 20 includes a driving portion that causes the first, second, and third vibrating arms 22A, 22B, and 22C to perform flexural vibration in the Z-axis direction as a third direction. The driving portion includes a first piezoelectric element 23A stacked on the temperature characteristic adjustment film 24A and disposed on the upper surface of the first vibrating arm 22A, a second piezoelectric element 23B stacked on the temperature characteristic adjustment film 24B and disposed on the upper surface of the second vibrating arm 22B, and a third piezoelectric element 23C stacked on the temperature characteristic adjustment film 24C and disposed on the upper surface of the third vibrating arm 22C.

The first, second, and third piezoelectric elements 23A, 23B, and 23C are shorter than the first, second, and third vibrating arms 22A, 22B, and 22C, and are disposed in a region of about half of the first, second, and third vibrating arms 22A, 22B, and 22C on the base end side. In addition, the first, second, and third piezoelectric elements 23A, 23B, and 23C are disposed across the base portion 210 and the first, second, and third vibrating arms 22A, 22B, and 22C. Each of the first, second, and third piezoelectric elements 23A, 23B, and 23C expands and contracts in the Y-axis direction by application of a driving voltage. The first, second, and third vibrating arms 22A, 22B, and 22C perform flexural vibration in the Z-axis direction due to expansion and contraction of the first, second, and third piezoelectric elements 23A, 23B, and 23C.

The first, second, and third piezoelectric elements 23A, 23B, and 23C have the same configuration, and as shown in FIG. 4, each includes a lower electrode 231 as a first electrode, a piezoelectric layer 232 disposed on an upper surface of the lower electrode 231, and an upper electrode 233 as a second electrode disposed on an upper surface of the piezoelectric layer 232. That is, the lower electrode 231 and the upper electrode 233 are disposed to face each other via the piezoelectric layer 232. Each of the lower electrode 231, the piezoelectric layer 232, and the upper electrode 233 is formed by a sputtering technique. However, a method for forming the lower electrode 231, the piezoelectric layer 232, and the upper electrode 233 is not particularly limited.

In addition, constituent materials of each portion of the first, second, and third piezoelectric elements 23A, 23B, and 23C are not particularly limited, but in the present embodiment, the piezoelectric layer 232 is made of aluminum nitride (AlN), and each of the lower electrode 231 and the upper electrode 233 is made of molybdenum (Mo). In particular, by making the lower electrode 231 of molybdenum, a crystal orientation of the aluminum nitride constituting the piezoelectric layer 232 is improved, and the piezoelectric constant of the piezoelectric layer 232 can be increased. Therefore, the electrical energy applied to the first, second, and third piezoelectric elements 23A, 23B, and 23C can be efficiently converted into the flexural vibration of the first, second, and third vibrating arms 22A, 22B, and 22C, and the vibration characteristics of the resonator element 20 are improved. Note that “each of the lower electrode 231 and the upper electrode 233 is made of molybdenum (Mo)” means that molybdenum (Mo) is used as a main material and a material other than molybdenum (Mo) may be contained.

As shown in FIG. 3, the first, second, and third piezoelectric elements 23A, 23B, and 23C are connected to wiring such that the first vibrating arm 22A located in a central portion and the second and third vibrating arms 22B and 22C located on both sides of the first vibrating arm 22A perform flexural vibration in opposite phases to each other. That is, the first, second, and third piezoelectric elements 23A, 23B, and 23C are connected to the wiring such that a first state in which the second and third vibrating arms 22B and 22C are flexurally deformed upward and the first vibrating arm 22A is flexurally deformed downward and a second state in which the second and third vibrating arms 22B and 22C are flexurally deformed downward and the first vibrating arm 22A is flexurally deformed upward are alternately repeated. Specifically, the lower electrodes 231 of the second and third piezoelectric elements 23B and 23C and the upper electrode 233 of the first piezoelectric element 23A are electrically coupled to the electrode pad PAD1 via wiring (not shown), and the upper electrodes 233 of the second and third piezoelectric elements 23B and 23C and the lower electrode 231 of the first piezoelectric element 23A are electrically coupled to the electrode pad PAD2 via wiring (not shown).

In this way, by causing the adjacent first, second, and third vibrating arms 22A, 22B, and 22C to perform flexural vibration in opposite phases to each other, the vibrations of the first, second, and third vibrating arms 22A, 22B, and 22C are at least partially canceled, and thus it is possible to effectively suppress vibration leakage of the resonator element 20. Therefore, the Q factor is increased, and the resonator element 20 which oscillates more easily is obtained. The flexural vibrations of the first, second, and third vibrating arms 22A, 22B, and 22C are greatly excited at the resonance frequency, and the impedance is minimized. As a result, connecting the MEMS element 1 to an oscillation circuit provides an oscillator that oscillates at a frequency determined by the resonance frequency.

The overall configuration of the resonator element 20 has been described above. Next, the configuration of the first, second, and third piezoelectric elements 23A, 23B, and 23C will be described in detail. The first, second, and third piezoelectric elements 23A, 23B, and 23C have the same configuration. Therefore, hereinafter, these are collectively described as “piezoelectric element 23”. In addition, hereinafter, the first, second, and third vibrating arms 22A, 22B, and 22C will be collectively described as “vibrating arm 22”.

As described above, by making the lower electrode 231 of molybdenum (Mo), the crystal orientation of the aluminum nitride constituting the piezoelectric layer 232 is improved, the piezoelectric constant of the piezoelectric layer 232 can be increased, and the vibration characteristics of the resonator element 20 are improved. However, the yield point of molybdenum (Mo) is much lower than that of silicon (Si) which is the constituent material of the vibrating arm 22 and aluminum nitride (AlN) which is the constituent material of the piezoelectric layer 232. The low yield point causes the following disadvantages.

To give some examples of the yield point, when a thickness of the vibrating arm 22 is 5 μm, a thickness of the lower electrode 231 and the upper electrode 233 is 25 nm, and a thickness of the piezoelectric layer 232 is 200 nm, the yield point of silicon (Si) constituting the vibrating arm 22 is 165 MPa, the yield point of molybdenum (Mo) constituting the lower electrode 231 and the upper electrode 233 is 400 MPa, and the yield point of aluminum nitride (AlN) constituting the piezoelectric layer 232 is 270 MPa. Further, since a relationship of the thicknesses is expressed as the vibrating arm 22>the piezoelectric layer 232>the lower electrode 231 and the upper electrode 233, a relationship of the stress applied to a root portion of the vibrating arm 22 is inversely expressed as the vibrating arm 22<the piezoelectric layer 232<the lower electrode 231 and the upper electrode 233. Therefore, the lower electrode 231 and the upper electrode 233 are rate-determining electrodes, that is, the lower electrode 231 and the upper electrode 233 reach the yield point earliest.

As described above, when the piezoelectric element 23 is expanded and contracted by energization, the vibrating arm 22 performs flexural vibration, and during the flexural vibration, a large stress is applied to the root portion of the vibrating arm 22, that is, a boundary between the vibrating arm 22 and the base portion 210. In addition, since the amplitude of the vibrating arm 22 increases as the driving voltage increases, the stress applied to the root portion of the vibrating arm 22 also increases.

Here, during the flexural vibration, when a stress applied to the lower electrode 231 and the upper electrode 233 is equal to or less than the yield point of molybdenum (Mo) which is the constituent material thereof, the lower electrode 231 and the upper electrode 233 are elastically deformed, and thus the root portion is deformed in proportion to the magnitude of the driving voltage. Therefore, the spring constant of the vibrating arm 22 does not change. However, during the flexural vibration, when a stress applied to the lower electrode 231 and the upper electrode 233 exceeds the yield point, plastic deformation occurs in the lower electrode 231 and the upper electrode 233, and the deformation of the root portion is not proportional to the magnitude of the driving voltage. That is, nonlinearity of the material occurs. Therefore, the spring constant of the vibrating arm 22 changes, and the resonance frequency of the resonator element 20 changes accordingly. Therefore, driving characteristics of the resonator element 20 deteriorate. The magnitude of the driving voltage varies depending on a user, and the above problem is more likely to occur for a user having a higher driving voltage.

In order to solve the above-described disadvantage, in the present embodiment, the lower electrode 231 and the upper electrode 233 are configured such that a stress exceeding the yield point is less likely to be applied. Specifically, as shown in FIG. 6 which is a partially enlarged view of FIG. 4, each of the lower electrode 231 and the upper electrode 233 includes a first portion Q1 overlapping the boundary between the base portion 210 and the vibrating arm 22 and a second portion Q2 located closer to a tip end side than the first portion Q1. The first portion Q1 extends from the boundary to both the tip end side and the base end side so as to straddle the boundary between the base portion 210 and the vibrating arm 22.

A film thickness T1 of the first portion Q1 is larger than a film thickness T2 of the second portion Q2. That is, T1>T2 is satisfied. As described above, when the vibrating arm 22 performs flexural vibration, a large stress is generated in the root portion of the vibrating arm 22, that is, the boundary between the vibrating arm 22 and the base portion 210. Therefore, by making the film thickness T1 of the first portion Q1, which overlaps the portion, larger than the film thickness T2 of the second portion Q2, the stress can be effectively dispersed in the first portion Q1, and a stress exceeding the yield point is less likely to be applied to the lower electrode 231 and the upper electrode 233. Therefore, a change in the resonance frequency of the resonator element 20 due to a nonlinearity of the constituent material of the lower electrode 231 and the upper electrode 233 is less likely to occur, and excellent vibration characteristics can be exhibited. The film thickness T1 of the first portion Q1 is not particularly limited, but is preferably, for example, about 100 μm or more and 150 μm or less. Consequently, the above-described effect becomes more remarkable.

Further, by making the film thickness T2 of the second portion Q2, which overlaps a location other than the root portion of the vibrating arm 22, smaller than the film thickness T1 of the first portion Q1, an overall thickness of the lower electrode 231 and the upper electrode 233 in a portion located on the vibrating arm 22 can be suppressed, and a vibration loss of the vibrating arm 22 due to the lower electrode 231 and the upper electrode 233 can be suppressed to be small. The film thickness T2 of the second portion Q2 is not particularly limited, but is preferably, for example, about 20 μm or more and 40 μm or less. Consequently, the above-described effect becomes more remarkable. As described above, by setting T1>T2, a change in the resonance frequency of the resonator element 20 due to a nonlinearity of the constituent material of the upper electrode 233 is less likely to occur, and the vibration loss of the vibrating arm 22 due to the lower electrode 231 and the upper electrode 233 can be suppressed to be small. Therefore, the driving characteristics of the resonator element 20 are improved.

Here, FIG. 7 shows the deviation of the resonance frequency of the resonator element 20 depending on the magnitude of the driving voltage (5 mV, 20 mV, and 40 mV) in a case when T1=T2, and FIG. 8 shows the deviation of the resonance frequency of the resonator element 20 depending on the magnitude of the driving voltage (5 mV, 20 mV, and 40 mV) in a case when T1>T2. As is clear from FIGS. 7 and 8, in the case of T1=T2, the resonance frequency of the resonator element 20 greatly changes depending on the magnitude of the driving voltage, whereas in the case of T1>T2, the resonance frequency of the resonator element 20 is maintained substantially constant regardless of the magnitude of the driving voltage. That is, the deviation of the resonance frequency depending on the magnitude of the driving voltage is smaller in the case of T1>T2 than in the case of T1=T2. Therefore, it can be seen that the above-described effect is exhibited.

In particular, in the resonator element 20 of the present embodiment, all of the first, second, and third piezoelectric elements 23A, 23B, and 23C satisfy a T1>T2 relationship. Therefore, the above-described effect becomes more remarkable, and the driving characteristics of the resonator element 20 are improved. However, without being limited thereto, for example, only the first piezoelectric element 23A may satisfy the T1>T2 relationship, and the second and third piezoelectric elements 23B and 23C need not satisfy the T1>T2 relationship. The first vibrating arm 22A located in the central portion tends to have a larger amplitude than the second and third vibrating arms 22B and 22C located on both sides thereof, and accordingly, a larger stress is applied to the root portion. Therefore, if at least the first piezoelectric element 23A satisfies the T1>T2 relationship, the above-described effect can be exhibited.

The first portion Q1 extends to the base end of the piezoelectric element 23. With such a configuration, the first portion Q1 can be formed larger, and accordingly, the electrical resistance of the lower electrode 231 and the upper electrode 233 can be reduced. Therefore, it is possible to efficiently drive the resonator element 20. Note that the base end portion of the piezoelectric element 23, that is, the portion located on the base portion 210, does not affect the vibration loss of the vibrating arm 22. Therefore, even when the first portion Q1 is extended to the base end of the piezoelectric element 23, the vibration characteristics of the vibrating arm 22 are not deteriorated. However, without being limited thereto, the first portion Q1 need not extend to the base end of the piezoelectric element 23.

Further, as shown in FIG. 9, the film thickness T1 of the first portion Q1 is larger than the film thickness T2 of the second portion Q2 in an entire region in the widthwise direction, that is, in the X-axis direction. As a result, the volume of the first portion Q1 is further increased, and accordingly, the stress can be more effectively dispersed in the first portion Q1. Therefore, the stress exceeding the yield point is even less likely to be applied to the lower electrode 231 and the upper electrode 233. In particular, in the present embodiment, the film thickness of the first portion Q1 is constant in the widthwise direction. However, without being limited thereto, in a part of the first portion Q1 in the widthwise direction, the film thickness T1 may be equal to the film thickness T2 or smaller than the film thickness T2.

The MEMS element 1 has been described above. As described above, the resonator element 20 provided in the MEMS element 1 includes: the vibrating substrate 21 including the base portion 210, and the first vibrating arm 22A, the second vibrating arm 22B, and the third vibrating arm 22C, each of the first, second, and third vibrating arms 22A, 22B, and 22C extending from the base portion 210 in the Y-axis direction as the first direction and being disposed side by side in the X-axis direction as the second direction orthogonal to the Y-axis direction, the first vibrating arm 22A being located between the second vibrating arm 22B and the third vibrating arm 22C; the first piezoelectric element 23A disposed across the first vibrating arm 22A and the base portion 210 to cause the first vibrating arm 22A to perform flexural vibration in the Z-axis direction as a third direction orthogonal to the X-axis direction and the Y-axis direction by expanding and contracting in the Y-axis direction; the second piezoelectric element 23B disposed across the second vibrating arm 22B and the base portion 210 to cause the second vibrating arm 22B to perform flexural vibration in the Z-axis direction by expanding and contracting in the Y-axis direction; and the third piezoelectric element 23C disposed across the third vibrating arm 22C and the base portion 210 to cause the third vibrating arm 22C to perform flexural vibration in the Z-axis direction by expanding and contracting in the Y-axis direction. Each of the first piezoelectric element 23A, the second piezoelectric element 23B, and the third piezoelectric element 23C includes the piezoelectric layer 232, the lower electrode 231 as the first electrode disposed between the piezoelectric layer 232 and the vibrating substrate 21, and the upper electrode 233 as the second electrode disposed to face the lower electrode 231 via the piezoelectric layer 232. In each of the lower electrode 231 and the upper electrode 233 of the first piezoelectric element 23A, the film thickness T1 of the first portion Q1 overlapping the boundary between the base portion 210 and the first vibrating arm 22A is larger than the film thickness T2 of the second portion Q2 located closer to the tip end side of the first vibrating arm 22A than the first portion Q1. With such a configuration, the stress can be effectively dispersed in the first portion Q1, and the stress exceeding the yield point is less likely to be applied to the lower electrode 231 and the upper electrode 233. Therefore, a change in the resonance frequency of the resonator element 20 due to nonlinearity of the constituent material of the lower electrode 231 and the upper electrode 233 is less likely to occur, and the resonator element 20 which can exhibit excellent vibration characteristics is obtained.

Further, as described above, also in the second piezoelectric element 23B and the third piezoelectric element 23C, the film thickness T1 of the first portion Q1 is larger than the film thickness T2 of the second portion Q2. With such a configuration, the second piezoelectric element 23B and the third piezoelectric element 23C can also exhibit the same effect as the first piezoelectric element 23A. Therefore, a change in the resonance frequency of the resonator element 20 is even less likely to occur, and the resonator element 20 which can exhibit further excellent vibration characteristics is obtained.

As described above, the film thickness T1 of the first portion Q1 is larger than the film thickness T2 of the second portion Q2 in the entire region in the X-axis direction. With such a configuration, the volume of the first portion Q1 is further increased, and accordingly, the stress can be more effectively dispersed in the first portion Q1. Therefore, the stress exceeding the yield point is even less likely to be applied to the lower electrode 231 and the upper electrode 233.

As described above, the first portion Q1 extends to the base end of the first piezoelectric element 23A. With such a configuration, the electrical resistance of the lower electrode 231 and the upper electrode 233 can be reduced. Therefore, it is possible to efficiently drive the resonator element 20.

Further, as described above, the first vibrating arm 22A performs flexural vibration with the second vibrating arm 22B and the third vibrating arm 22C in opposite phases to each other in the Z-axis direction. With such a configuration, the vibrations of the first, second, and third vibrating arms 22A, 22B, and 22C are at least partially canceled, and it is possible to effectively suppress vibration leakage of the resonator element 20. Therefore, the Q factor is increased, and the resonator element 20 which oscillates more easily is obtained.

### Second Embodiment

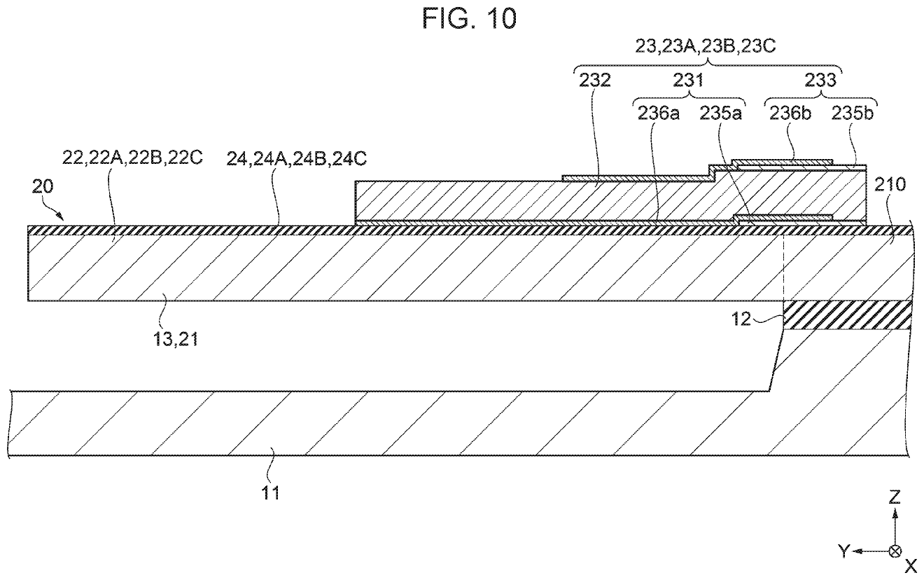

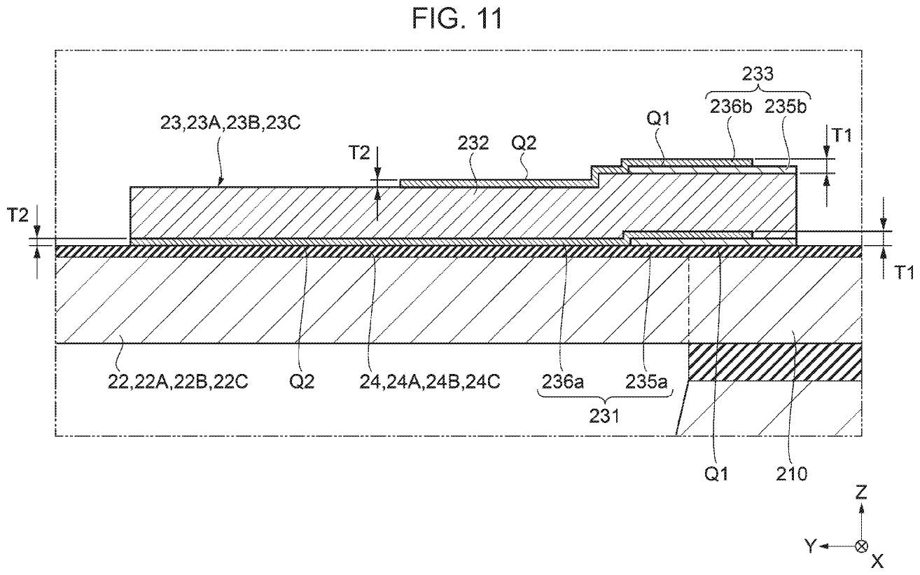

FIG. 10 is a sectional view of a vibrating arm included in the resonator element according to the second embodiment. FIG. 11 is a sectional view of a piezoelectric element included in the resonator element according to the second embodiment.

The MEMS element 1 of the present embodiment is mainly the same as that of the first embodiment described above except that the configurations of the lower electrode 231 and the upper electrode 233 of the piezoelectric element 23 are different. In the following description, the present embodiment will be described focusing on differences from the first embodiment described above, and the description of the same matters will be omitted. In addition, in the drawing of the present embodiment, the same reference numerals are assigned to the same configurations as in the embodiment described above.

As shown in FIGS. 10 and 11, the lower electrode 231 of the present embodiment includes a base-end-side electrode film 235a as a first electrode film disposed on the base end side, and a tip-end-side electrode film 236a as a second electrode film disposed on the tip end side. Similarly, the upper electrode 233 of the present embodiment includes a base-end-side electrode film 235b as a first electrode film disposed on the base end side and a tip-end-side electrode film 236b as a second electrode film disposed on the tip end side. In addition, the base-end-side electrode films 235a and 235b and the tip-end-side electrode films 236a and 236b are disposed across the boundary between the base portion 210 and the vibrating arm 22. A position at which each of the base-end-side electrode films 235a and 235b and the tip-end-side electrode films 236a and 236b overlaps the boundary between the base portion 210 and the vibrating arm 22 is the first portion Q1. Therefore, on the boundary between the base portion 210 and the vibrating arm 22, a tip end portion of the base-end-side electrode film 235a and a base end portion of the tip-end-side electrode film 236a overlap each other, and a tip end portion of the base-end-side electrode film 235b and a base end portion of the tip-end-side electrode film 236b overlap each other. Specifically, in such a way that upper sides of the tip end portions of the base-end-side electrode films 235a and 235b are covered by the base end portions of the tip-end-side electrode films 236a and 236b, the base end portions of the tip-end-side electrode films 236a and 236b overlap the tip end portions of the base-end-side electrode films 235a and 235b. The base-end-side electrode films 235a and 235b are connected to the tip-end-side electrode films 236a and 236b. In such a configuration, the first portion Q1 is formed at a portion where the base-end-side electrode films 235a and 235b and the tip-end-side electrode films 236a and 236b overlap each other, and the second portion Q2 is formed at a portion located closer to the tip end side of the vibrating arm 22 than the first portion Q1 of the tip-end-side electrode films 236a and 236b.

In the present embodiment, each of the tip-end-side electrode films 236a and 236b is made of molybdenum (Mo). By making the tip-end-side electrode films 236a and 236b of molybdenum, the crystal orientation of the aluminum nitride constituting the piezoelectric layer 232 is improved, and the piezoelectric constant of the piezoelectric layer 232 can be increased. Therefore, the electrical energy applied to the first, second, and third piezoelectric elements 23A, 23B, and 23C can be efficiently converted into the flexural vibration of the first, second, and third vibrating arms 22A, 22B, and 22C, and the vibration characteristics of the resonator element 20 are improved. Note that “each of the tip-end-side electrode films 236a and 236b is made of molybdenum (Mo)” means that molybdenum (Mo) is used as a main material and a material other than molybdenum (Mo) may be contained.

In the present embodiment, the base-end-side electrode films 235a and 235b are made of a material having a higher yield point than that of the constituent material of the tip-end-side electrode films 236a and 236b. In particular, in the present embodiment, the base-end-side electrode films 235a and 235b are made of titanium nitride (TiN). By including the base-end-side electrode films 235a and 235b, which have a high yield point, in the first portion Q1, the stress exceeding the yield point is less likely to be applied to the lower electrode 231 and the upper electrode 233. Note that “each of the base-end-side electrode films 235a and 235b is made of titanium nitride (TiN)” means that titanium nitride (TiN) is used as a main material and a material other than titanium nitride (TiN) may be contained.

To give some examples of the yield point, when a thickness of the vibrating arm 22 is 5 μm, a thickness of the tip-end-side electrode films 236a and 236b and the base-end-side electrode films 235a and 235b is 25 nm, and a thickness of the piezoelectric layer 232 is 200 nm, the yield point of molybdenum (Mo) constituting the tip-end-side electrode films 236a and 236b is 400 MPa, and the yield point of titanium nitride (TiN) constituting the base-end-side electrode films 235a and 235b is 600 MPa. Further, the yield point of aluminum nitride (AlN) constituting the piezoelectric layer 232 is 270 MPa, and the yield point of silicon (Si) constituting the vibrating arm 22 is 165 MPa.

The surface of the base-end-side electrode films 235a and 235b may be subjected to ashing treatment using oxygen gas to form an amorphous layer containing oxygen (O) which is easily bonded to aluminum on the surface of the base-end-side electrode films 235a and 235b. As a result, the crystal orientation of the aluminum nitride (AlN) is improved, and the piezoelectric constant of the piezoelectric layer 232 can be increased similarly to molybdenum (Mo).

As described above, in the resonator element 20 of the present embodiment, the first portion Q1 includes the base-end-side electrode films 235a and 235b as the first electrode film, and the tip-end-side electrode films 236a and 236b as the second electrode film stacked on the base-end-side electrode films 235a and 235b and made of a material having a yield point lower than that of the constituent material of the base-end-side electrode films 235a and 235b. With such a configuration, for example, by making the base-end-side electrode films 235a and 235b of titanium nitride (TiN), the stress exceeding the yield point is less likely to be applied to the lower electrode 231 and the upper electrode 233, and by making the tip-end-side electrode films 236a and 236b of molybdenum (Mo), the orientation of the piezoelectric layer 232 can be improved while the vibration loss of the vibrating arm 22 is suppressed to be small.

In the present embodiment, the film thickness of the base-end-side electrode films 235a and 235b is substantially equal to the film thickness of the tip-end-side electrode films 236a and 236b. The film thickness is both 25 nm, for example. As shown in FIG. 11, the film thickness T2 of the second portion Q2 is the film thickness of the tip-end-side electrode films 236a and 236b, and the film thickness T1 of the first portion Q1 is the film thickness of an overlap of the tip-end-side electrode films 236a and 236b and the base-end-side electrode films 235a and 235b. Therefore, the film thickness T1 of the first portion Q1 is larger than the film thickness T2 of the second portion Q2. That is, T1>T2 is satisfied. As described above, when the vibrating arm 22 performs flexural vibration, a large stress is generated in the root portion of the vibrating arm 22, that is, the boundary between the vibrating arm 22 and the base portion 210. Therefore, by making the film thickness T1 of the first portion Q1, which overlaps the portion, larger than the film thickness T2 of the second portion Q2, the stress can be effectively dispersed in the first portion Q1, and the stress exceeding the yield point is less likely to be applied to the lower electrode 231 and the upper electrode 233. Therefore, a change in the resonance frequency of the resonator element 20 due to a nonlinearity of the constituent material of the lower electrode 231 and the upper electrode 233 is less likely to occur, and excellent vibration characteristics can be exhibited.

Similarly to the first embodiment, the first portion Q1 may extend to the base end of the piezoelectric element 23. With such a configuration, the first portion Q1 can be formed larger, and accordingly, the electrical resistance of the lower electrode 231 and the upper electrode 233 can be reduced. Therefore, it is possible to efficiently drive the resonator element 20. Note that the base end portion of the piezoelectric element 23, that is, the portion located on the base portion 210, does not affect the vibration loss of the vibrating arm 22. Therefore, even when the first portion Q1 is extended to the base end of the piezoelectric element 23, the vibration characteristics of the vibrating arm 22 are not deteriorated. However, without being limited thereto, the first portion Q1 need not extend to the base end of the piezoelectric element 23.

In particular, in the resonator element 20 of the present embodiment, in all of the first, second, and third piezoelectric elements 23A, 23B, and 23C, the base-end-side electrode films 235a and 235b are made of a material having a higher yield point than that of the constituent material of the tip-end-side electrode films 236a and 236b. Therefore, the above-described effect becomes more remarkable, and the vibration characteristics of the resonator element 20 are improved. However, without being limited thereto, a piezoelectric element in which the base-end-side electrode films 235a and 235b are made of a material having a higher yield point than that of the constituent material of the tip-end-side electrode films 236a and 236b may be included, for example, only in the first piezoelectric element 23A. The first vibrating arm 22A located in the central portion tends to have a larger amplitude than the second and third vibrating arms 22B and 22C located on both sides thereof, and accordingly, a larger stress is applied to the root portion. Therefore, if at least the base-end-side electrode films 235a and 235b of the first piezoelectric element 23A are made of a material having a higher yield point than that of the constituent material of the tip-end-side electrode films 236a and 236b, the above-described effect can be exhibited.

The MEMS element 1 has been described above. As described above, the resonator element 20 provided in the MEMS element 1 includes: the vibrating substrate 21 including the base portion 210, and the first vibrating arm 22A, the second vibrating arm 22B, and the third vibrating arm 22C, each of the first, second, and third vibrating arms 22A, 22B, and 22C extending from the base portion 210 in the Y-axis direction as the first direction and being disposed side by side in the X-axis direction as the second direction orthogonal to the Y-axis direction, the first vibrating arm 22A being located between the second vibrating arm 22B and the third vibrating arm 22C; the first piezoelectric element 23A disposed across the first vibrating arm 22A and the base portion 210 to cause the first vibrating arm 22A to perform flexural vibration in the Z-axis direction as a third direction orthogonal to the X-axis direction and the Y-axis direction by expanding and contracting in the Y-axis direction; the second piezoelectric element 23B disposed across the second vibrating arm 22B and the base portion 210 to cause the second vibrating arm 22B to perform flexural vibration in the Z-axis direction by expanding and contracting in the Y-axis direction; and the third piezoelectric element 23C disposed across the third vibrating arm 22C and the base portion 210 to cause the third vibrating arm 22C to perform flexural vibration in the Z-axis direction by expanding and contracting in the Y-axis direction. Each of the first piezoelectric element 23A, the second piezoelectric element 23B, and the third piezoelectric element 23C includes the piezoelectric layer 232, the lower electrode 231 as the first electrode disposed between the piezoelectric layer 232 and the vibrating substrate 21, and the upper electrode 233 as the second electrode disposed to face the lower electrode 231 via the piezoelectric layer 232. Each of the lower electrode 231 and the upper electrode 233 in the first piezoelectric element 23A includes the base-end-side electrode films 235a and 235b as the first electrode film in the first portion Q1 overlapping the boundary between the base portion 210 and the first vibrating arm 22A, and includes the tip-end-side electrode films 236a and 236b as the second electrode film in the second portion Q2 located closer to the tip end side of the first vibrating arm 22A than the first portion Q1. The base-end-side electrode films 235a and 235b are connected to the tip-end-side electrode films 236a and 236b, and are made of a material having a higher yield point than that of the constituent material of the tip-end-side electrode films 236a and 236b. Therefore, a change in the resonance frequency of the resonator element 20 due to a nonlinearity of the constituent material of the lower electrode 231 and the upper electrode 233 is less likely to occur, and the resonator element 20 can exhibit excellent vibration characteristics.

In addition, as described above, the base-end-side electrode films 235a and 235b are formed so as to straddle the boundary between the base portion 210 and the first vibrating arm 22A, and overlap the tip-end-side electrode films 236a and 236b in the first portion Q1. With such a configuration, the film thickness T1 of the first portion Q1 is larger than the film thickness T2 of the second portion Q2. As a result, the stress can be effectively dispersed in the first portion Q1, and the stress exceeding the yield point is even less likely to be applied to the lower electrode 231 and the upper electrode 233.

As described above, also in the second piezoelectric element 23B and the third piezoelectric element 23C, the base-end-side electrode films 235a and 235b are made of a material having a higher yield point than that of the constituent material of the tip-end-side electrode films 236a and 236b. With such a configuration, the second piezoelectric element 23B and the third piezoelectric element 23C can also exhibit the same effect as the first piezoelectric element 23A. Therefore, a change in the resonance frequency of the resonator element 20 is even less likely to occur, and the resonator element 20 can exhibit more excellent vibration characteristics.

As described above, the base-end-side electrode films 235a and 235b are made of titanium nitride (TiN), and the tip-end-side electrode films 236a and 236b are made of molybdenum (Mo). With such a configuration, the orientation of the aluminum nitride (AlN) formed on the molybdenum (Mo) can be improved. Therefore, the electromechanical coupling coefficient between aluminum nitride (AlN) and molybdenum (Mo) can be improved, and the vibration loss can be suppressed to be small.

Further, as described above, the first vibrating arm 22A performs flexural vibration with the second vibrating arm 22B and the third vibrating arm 22C in opposite phases to each other in the Z-axis direction. With such a configuration, the vibrations of the first, second, and third vibrating arms 22A, 22B, and 22C are at least partially canceled, and it is possible to effectively suppress the vibration leakage of the resonator element 20. Therefore, the resonator element 20 can increase the Q factor and can oscillate more easily.

### Modification Examples of Second Embodiment

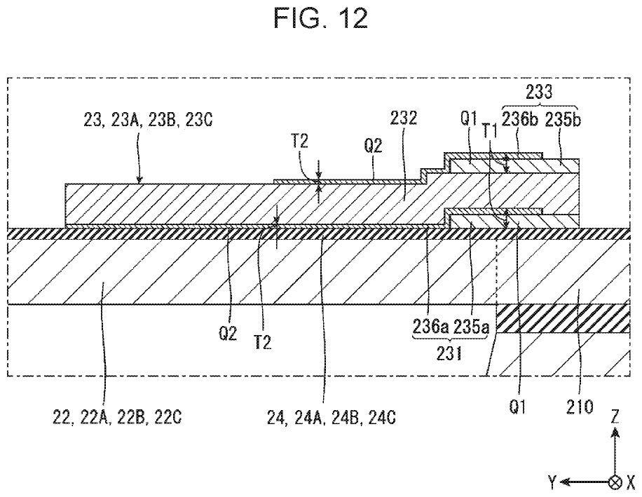

In the second embodiment, it has been described that the film thickness of the tip-end-side electrode films 236a and 236b made of molybdenum (Mo) is substantially equal to the film thickness of the base-end-side electrode films 235a and 235b made of titanium nitride (TiN), but the present disclosure is not particularly limited thereto. For example, as shown in FIG. 12, the film thickness of the tip-end-side electrode films 236a and 236b may be smaller than the film thickness of the base-end-side electrode films 235a and 235b. The film thickness of the tip-end-side electrode films 236a and 236b is preferably as small as possible as long as the function of improving the crystal orientation of aluminum nitride can be exhibited. With such a configuration, it is possible to suppress the vibration loss of the vibrating arm 22 due to the lower electrode 231 and the upper electrode 233 to be small.

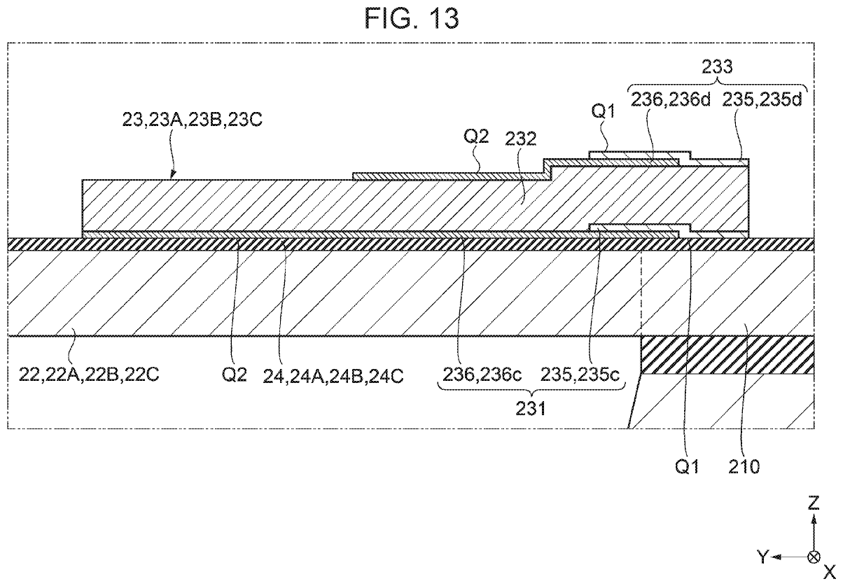

In addition, although it has been described that the base end portions of the tip-end-side electrode films 236a and 236b overlap the tip end portions of the base-end-side electrode films 235a and 235b in such a way that the upper sides of the tip end portions of the base-end-side electrode films 235a and 235b are covered by the base end portions of the tip-end-side electrode films 236a and 236b, the present disclosure is not particularly limited thereto. For example, as shown in FIG. 13, tip end portions of base-end-side electrode films 235c and 235d may overlap base end portions of tip-end-side electrode films 236c and 236d in such a way that upper sides of the base end portions of the tip-end-side electrode films 236c and 236d are covered by the tip end portions of the base-end-side electrode films 235c and 235d. Even with such a configuration, the same effect as the above-described effect can be obtained.

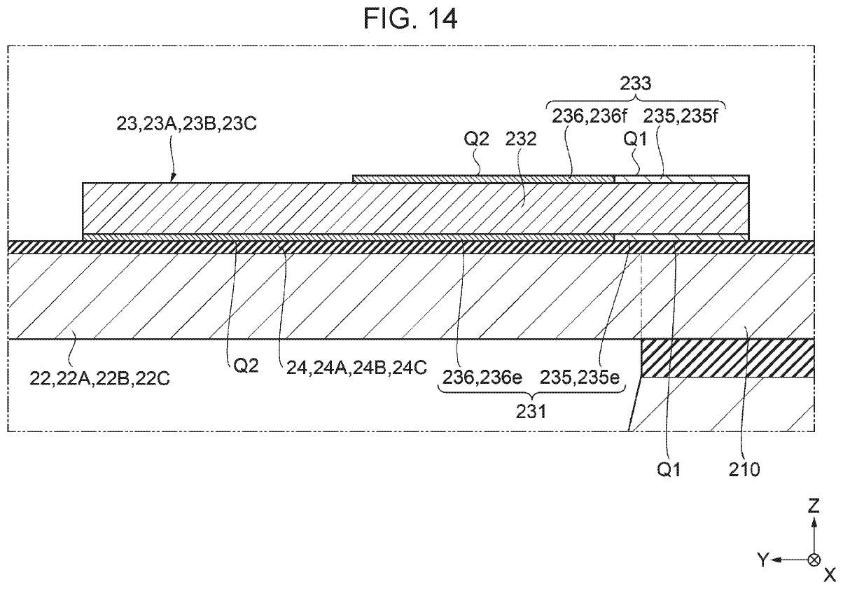

In addition, although it has been described that the base-end-side electrode films 235a and 235b overlap the tip-end-side electrode films 236a and 236b in the first portion Q1, the present disclosure is not particularly limited thereto. For example, as shown in FIG. 14, base-end-side electrode films 235e and 235f and tip-end-side electrode films 236e and 236f may be connected in the Y-axis direction without overlapping each other. In this case, it is desirable that the base-end-side electrode films 235e and 235f are disposed across the boundary between the base portion 210 and the vibrating arm 22. With such a configuration, the film thicknesses of the upper electrode 233 and the lower electrode 231 can be made uniform in the Y-axis direction. In addition, the thickness of the piezoelectric layer 232 can be made uniform in the Y-axis direction. Accordingly, the first, second, and third vibrating arms 22A, 22B, and 22C can vibrate equally on the +Z side and the −Z side. As a result, the resonator element 20 can increase the Q factor and can oscillate more easily.

Although the resonator element 20 according to the present disclosure has been described based on the embodiments shown in the drawings, the present disclosure is not limited thereto. A configuration of each section can be replaced with another configuration having substantially the same function. Furthermore, any other components may be added to the present disclosure.

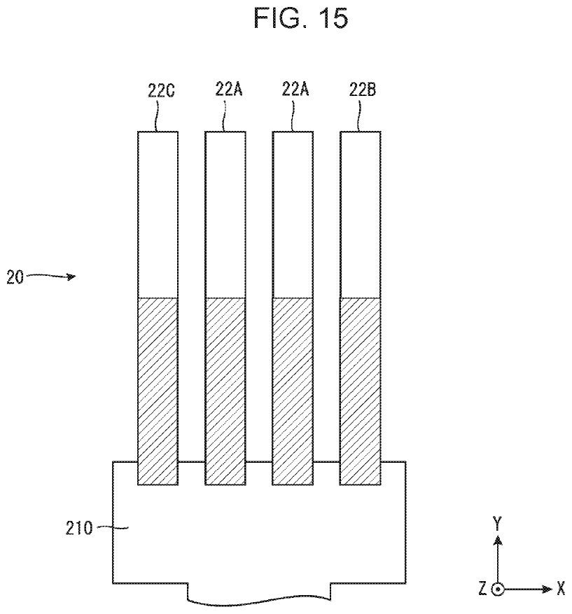

For example, in the embodiments described above, the resonator element 20 has three vibrating arms, but the number of vibrating arms is not limited thereto. For example, as shown in FIG. 15, four vibrating arms may be provided, or five or more vibrating arms may be provided. In a configuration shown in FIG. 15, two arms located in the center are both first vibrating arms 22A, and arms located on both sides thereof are a second vibrating arm 22B and a third vibrating arm 22C. However, as long as a relationship in which the second and third vibrating arms 22B and 22C are located on both sides of the first vibrating arm 22A is satisfied, which of the vibrating arms corresponds to which of the first, second, and third vibrating arms 22A, 22B, and 22C is not particularly limited.

What is claimed is:

1. A resonator element, when three axes orthogonal to each other are defined as an X-axis, a Y-axis, and a Z-axis, and a direction along the X-axis is defined as an X-axis direction, a direction along the Y-axis is defined as a Y-axis direction, and a direction along the Z-axis is defined as a Z-axis direction, the resonator element comprising:
a vibrating substrate including: a base portion; and a first vibrating arm, a second vibrating arm, and a third vibrating arm, each of the first, second, and third vibrating arms extending from the base portion in the Y-axis direction and being arranged side by side in the X-axis direction, the first vibrating arm being disposed between the second vibrating arm and the third vibrating arm in plan view from the Z-axis direction;
a first piezoelectric element disposed across the first vibrating arm and the base portion to cause the first vibrating arm to perform flexural vibration in the Z-axis direction by expanding and contracting in the Y-axis direction;
a second piezoelectric element disposed across the second vibrating arm and the base portion to cause the second vibrating arm to perform flexural vibration in the Z-axis direction by expanding and contracting in the Y-axis direction; and
a third piezoelectric element disposed across the third vibrating arm and the base portion to cause the third vibrating arm to perform flexural vibration in the Z-axis direction by expanding and contracting in the Y-axis direction,
wherein each of the first piezoelectric element, the second piezoelectric element, and the third piezoelectric element includes:
a piezoelectric layer;
a lower electrode disposed between the piezoelectric layer and the vibrating substrate; and
an upper electrode overlapping the lower electrode via the piezoelectric layer in plan view from the Z-axis direction, and
in the first vibrating arm, the second vibrating arm, and the third vibrating arm,
when a region overlapping a boundary between the base portion and a vibrating arm is defined as a first portion, and
when a region closer to a tip end side of the vibrating arm than the first portion is defined as a second portion,
in each of the lower electrode and the upper electrode of the first piezoelectric element,
a film thickness of the first portion is larger than a film thickness of the second portion.

2. The resonator element according to claim 1,
wherein, in the second piezoelectric element and the third piezoelectric element,
the film thickness of the first portion is larger than the film thickness of the second portion.

3. The resonator element according to claim 1,
wherein the film thickness of the first portion is larger than the film thickness of the second portion in an entire region in the X-axis direction.

4. The resonator element according to claim 1,
wherein the first portion extends to a base end of the first piezoelectric element.

5. The resonator element according to claim 1,
wherein the first portion includes:
a first electrode film; and
a second electrode film stacked on the first electrode film and made of a material having a lower yield point than that of a constituent material of the first electrode film.

6. The resonator element according to claim 1,
wherein the first vibrating arm performs flexural vibration with the second vibrating arm and the third vibrating arm in opposite phases to each other in the Z-axis direction.

7. A resonator element, when three axes orthogonal to each other are defined as an X-axis, a Y-axis, and a Z-axis, and a direction along the X-axis is defined as an X-axis direction, a direction along the Y-axis is defined as a Y-axis direction, and a direction along the Z-axis is defined as a Z-axis direction, the resonator element comprising:
a vibrating substrate including: a base portion; and a first vibrating arm, a second vibrating arm, and a third vibrating arm, each of the first, second, and third vibrating arms extending from the base portion in the Y-axis direction and being arranged side by side in the X-axis direction, the first vibrating arm being disposed between the second vibrating arm and the third vibrating arm in plan view from the Z-axis direction;
a first piezoelectric element disposed across the first vibrating arm and the base portion to cause the first vibrating arm to perform flexural vibration in the Z-axis direction by expanding and contracting in the Y-axis direction;
a second piezoelectric element disposed across the second vibrating arm and the base portion to cause the second vibrating arm to perform flexural vibration in the Z-axis direction by expanding and contracting in the Y-axis direction; and
a third piezoelectric element disposed across the third vibrating arm and the base portion to cause the third vibrating arm to perform flexural vibration in the Z-axis direction by expanding and contracting in the Y-axis direction,
wherein each of the first piezoelectric element, the second piezoelectric element, and the third piezoelectric element includes:
a piezoelectric layer;
a lower electrode disposed between the piezoelectric layer and the vibrating substrate; and
an upper electrode overlapping the lower electrode via the piezoelectric layer in plan view from the Z-axis direction, and
in the first vibrating arm, the second vibrating arm, and the third vibrating arm,
when a region overlapping a boundary between the base portion and a vibrating arm is defined as a first portion, and
when a region closer to a tip end side of the vibrating arm than the first portion is defined as a second portion,
each of the lower electrode and the upper electrode of the first piezoelectric element includes:
a first electrode film in the first portion; and
a second electrode film in the second portion,
the first electrode film being connected to the second electrode film,
the first electrode film being made of a material having a higher yield point than that of a constituent material of the second electrode film.

8. The resonator element according to claim 7,
wherein, in the first vibrating arm,
the first electrode film is disposed to straddle the boundary between the base portion and the vibrating arm, and
the first electrode film overlaps the second electrode film in the first portion.

9. The resonator element according to claim 7,
wherein, in the second piezoelectric element and the third piezoelectric element,
the first electrode film is made of a material having a higher yield point than that of a constituent material of the second electrode film.

10. The resonator element according to claim 7,
wherein the first electrode film is made of titanium nitride, and the second electrode film is made of molybdenum.

11. The resonator element according to claim 7,
wherein the first vibrating arm performs flexural vibration with the second vibrating arm and the third vibrating arm in opposite phases to each other in the Z-axis direction.
